(19) United States
(12) Patent Application Publication
(10) Pub. No.: US 2008/0013002 A1
(43) Pub. Date: Jan. 17, 2008

(54) Lenticular lens and method of fabricating thereof

(76) Inventors: Hyung Ki Hong, Seoul (KR); Dong Kyu Yoon, Anyang-si (KR)

Correspondence Address: MCKENNA LONG & ALDRIDGE LLP, 1900 K STREET, NW, WASHINGTON, DC, 20006, US

(21) Appl. No.: 11/819,723

(22) Filed: Jun. 28, 2007

(30) Foreign Application Priority Data
Jun. 29, 2006 (KR) P2006-059286
Jun. 29, 2006 (KR) P2006-059335

(51) Int. Cl. G02F 1/1337; G02F 1/13; H01L 21/02; G02F 1/1335

(52) U.S. Cl. 349/15; 349/132; 349/200; 438/30; 257/E21.52

(57) ABSTRACT

A lenticular lens includes an upper plate including an upper transparent electrode and having a plurality of lens surfaces having a curved surface shape; an upper alignment film on the lens surfaces; a lower plate having a lower transparent electrode and a lower alignment film; and a liquid crystal layer between the upper plate and the lower plate to be driven by an electric field applied by the upper transparent electrode and the lower transparent electrode.

This application claims the benefit of Korean Patent Application No. P2006-059286, filed on Jun. 29, 2006 and Korean Patent Application No. P2006-059335 filed on Jun. 29, 2006, which is hereby incorporated by reference for all purposes as if fully set forth herein.

### BACKGROUND OF THE INVENTION

1. Field of the Invention

The present invention relates to a stereoscopic image display device, and more particularly to a lenticular lens having an alignment film uniformly formed on curved surface thereof. Further, the present invention relates to a method of fabricating a lenticular lens for improving switching characteristics of liquid crystal molecules using the alignment film.

2. Discussion of the Related Art

A stereoscopic image display device displays an image having a three-dimensional perspective. A three-dimensional perspective is generated when different image signals recognized by a left eye and a right eye are blended into one. The stereoscopic image display device has been developed on the basis of a binocular type.

A binocular type, i.e. a type using a binocular disparity, displays an image shot by a camera corresponding to a left eye position and an image shot by a camera corresponding to a right eye position from the same display panel. Further, the binocular-type displays a left eye image into the left eye and displays a right eye image into the right eye, thereby realizing a three-dimensional stereoscopic image. The binocular type stereoscopic display devices are classified into devices using a slit barrier and devices using a lenticular lens.

Referring to FIG. 1, a device using a slit barrier selectively cuts off light irradiated from a display panel 11 using a slit barrier 12 and separates each path of a light of the left eye image and a light of the right eye image to realize a three-dimensional stereoscopic image. Such a device using the slit barrier 12 activates a slit barrier 12 of a liquid crystal display device when the viewer sees and hears a three-dimensional stereoscopic image, and deactivates the slit barrier 12 when the viewer sees and hears a two-dimensional image. Thus, the device using the slit barrier 12 has an advantage in that a three-dimensional image mode and a two-dimensional image mode are easily changed. However, the device using the slit barrier 12 has a disadvantage in that a brightness loss is increased because a light transmitted through the slit barrier 12 is reduced by more than 50%.

Referring to FIG. 2, a device using the lenticular lens separates a right eye image and a left eye image using a lenticular lens 21 to realize a three-dimensional stereoscopic image. Such a device using a lenticular lens has an advantage of a small brightness loss compared to the device using the slit barrier. However, since the device using the lenticular lens does not switch optical characteristics, only three-dimensional stereoscopic images are realized. Further, it is impossible to switch between the three-dimensional stereoscopic image and a two-dimensional image.

In order to solve these problems, a lenticular lens that switches optical characteristics (hereinafter, referred to as “liquid crystal lenticular lens”) has been suggested. A liquid crystal lenticular lens electrically controls a refractive index of a liquid crystal to realize a lenticular lens, thereby switching between a three-dimensional image and a two-dimensional image.

Referring to FIG. 3 and FIG. 4, a liquid crystal lenticular lens 30 is spaced a predetermined distance in front of a display panel 31.

Referring to FIG. 3, liquid crystal molecules 34 are aligned in a horizontal direction in the three-dimensional image mode, and the liquid crystal lenticular lens 30 refracts a light from a display panel 31 and separates paths of a light corresponding to a right eye image and a light corresponding to a light eye image. An electric field is not applied to the liquid crystal molecules 34 in the three-dimensional image mode.

Referring to FIG. 4, the liquid crystal molecules 34 are driven to be turned up in the two-dimensional image mode when an electric field is applied. As a result, a difference of the refractive index of the liquid crystal molecules 34 and a transparent substrate 35 is reduced, so that a light irradiated from the display panel 31 is transmitted into the liquid crystal lenticular lens 30 substantially without alteration.

Referring to FIG. 5, such a liquid crystal lenticular lens 30 includes an upper plate 41 and a lower plate 40 arranged in opposition to each other with a liquid crystal layer therebetween.

The upper plate 41 includes a transparent electrode 36, and a transparent substrate 35 provided on the transparent electrode 36. A plurality of carving patterns 35a are formed in the curved surface of concave lens shape on the transparent substrate 35.

The lower plate 40 includes a transparent electrode 32 provided on a lower transparent substrate, and an alignment film 33 coated on the transparent electrode 32. The alignment film 33 is a polyimide alignment film, and is rubbed along an aligning direction 33a of the liquid crystal by a rubbing process to determine a pre-tilt of the liquid crystal molecules 34.

The liquid crystal molecules 34 are a positive liquid crystal. The positive liquid crystal is a liquid crystal defined such that a major axis direction dielectric constant (ε∥) of the liquid crystal molecules is more than a minor axis direction dielectric constant (ε⊥), that is, Δε>0, and is aligned in a horizontal direction by the alignment film 33. Further, the major axis direction of the liquid crystal molecules is aligned in parallel in a direction of an applying electric field.

If an alignment film is not formed on the upper plate, the liquid crystal molecules 34 in the liquid crystal lenticular lens 30 cannot be rapidly and uniformly switched. It would be difficult to form an alignment film having uniform thickness in the curved surface of the carving pattern 35a on the upper plate followed by uniformly carrying out a contact rubbing process of the alignment film. In the related art, a polyimide alignment film 33 is formed at only lower plate 40 in the liquid crystal lenticular lens 30, a switching speed of the liquid crystal molecules 34 is slow, and the liquid crystal molecules 34 are not uniformly switched.

### SUMMARY OF THE INVENTION

Accordingly, the present invention is directed to a lenticular lens and method of fabricating thereof that substantially obviates one or more of the problems due to limitations and disadvantages of the related art.

An advantage of the present invention is to provide a lenticular lens including an alignment film uniformly formed on a lens surface of curved surface type.

It is another object of the present invention to provide a lenticular lens and a fabricating method thereof that are adaptive for improving a switching characteristics of liquid crystal molecules using the alignment film.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a lenticular lens, includes an upper plate including an upper transparent electrode and having a plurality of lens surfaces having a curved surface shape; an upper alignment film on the lens surfaces; a lower plate having a lower transparent electrode and a lower alignment film; and a liquid crystal layer between the upper plate and the lower plate to be driven by an electric field applied by the upper transparent electrode and the lower transparent electrode.

In another aspect of the present invention, a method of fabricating a lenticular lens includes preparing an upper plate having an upper transparent electrode and a plurality of lens surfaces having a curved surface shape; forming an upper alignment film at the lens surfaces; preparing a lower plate having a lower transparent electrode; forming a lower alignment film at the lower plate; and forming a liquid crystal layer adjacent to the alignment films between the upper plate and the lower plate.

In yet another aspect of the present invention, a stereoscopic image display device includes: a display panel; and a liquid crystal lenticular lens spaced a predetermined distance from the display panel, the lenticular lens including: an upper plate having an upper transparent electrode and a plurality of lens surfaces having a curved surface shape; an upper alignment film uniformly on the lens surfaces; a lower plate having a lower transparent electrode and a lower alignment film; and a liquid crystal layer provided between the upper plate and the lower plate to be driven by an electric field applied by the upper transparent electrode and the lower transparent electrode.

It is to be understood that both the foregoing general description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description, serve to explain the principles of the invention.

In the drawings:

FIG. 1 is a diagram showing a related art stereoscopic image display device using a slit barrier;

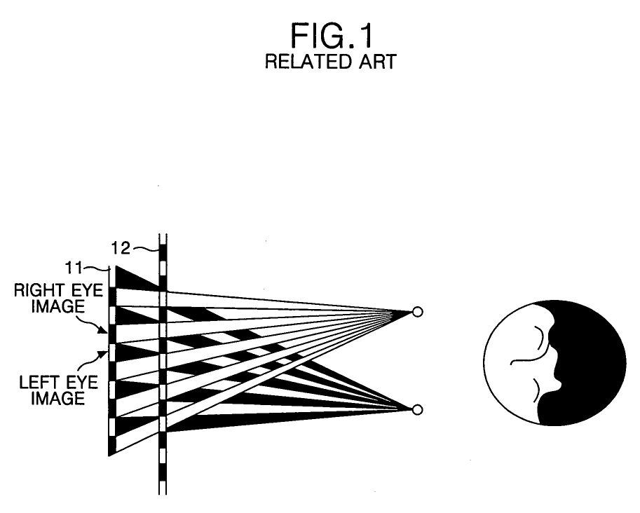

FIG. 2 is a diagram showing a related art stereoscopic image display device using a lenticular lens;

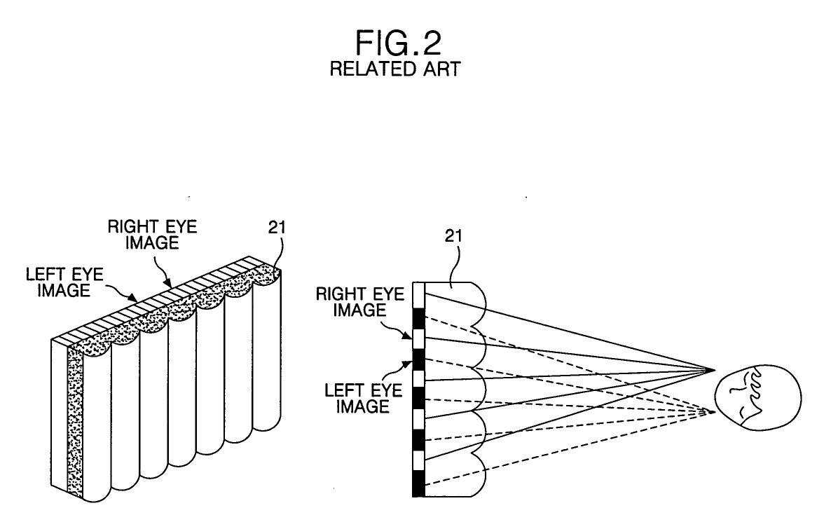

FIG. 3 is a diagram showing a light path on the condition that an electric field is not applied to liquid crystal molecules in the related art lenticular lens;

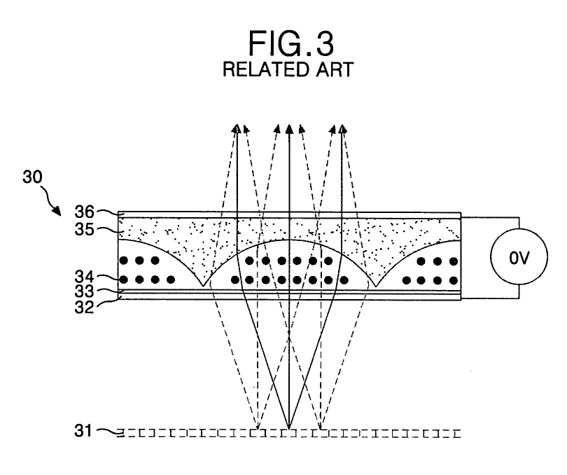

FIG. 4 is a diagram showing the light path on the condition that the electric field is applied to the liquid crystal molecules in the related art lenticular lens;

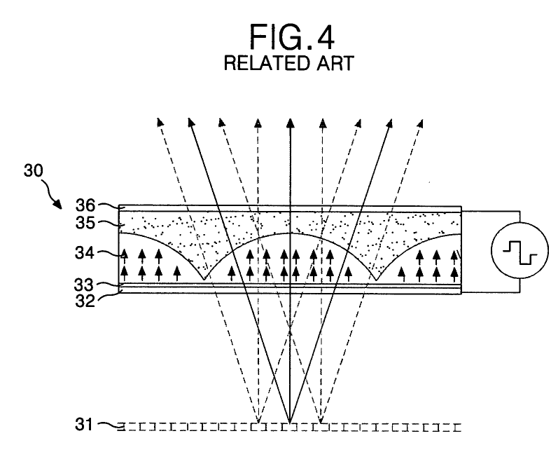

FIG. 5 is a perspective view showing a structure of the lenticular lens in FIG. 3 and FIG. 4;

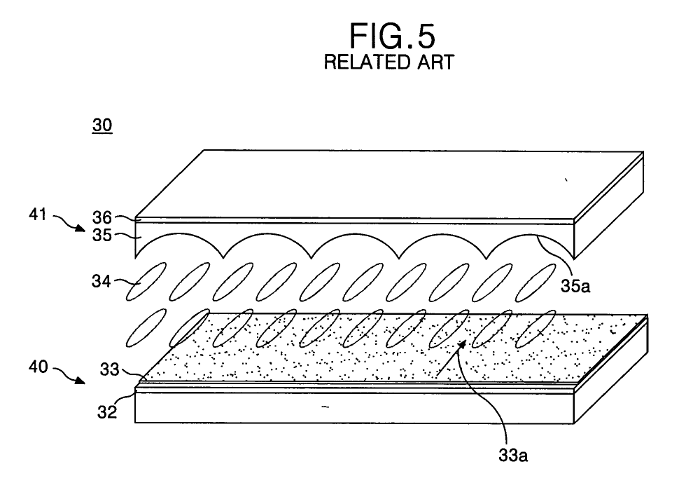

FIG. 6 is a perspective view showing a structure of the lenticular lens according to a first embodiment of the present invention;

FIG. 7 is a diagram showing a process of assembling and orienting a carbon nano-tube film in a process of forming an alignment film of the lenticular lens shown in FIG. 6 step by step;

FIG. 8 is a diagram showing an angle between a carbon nano-tube and a substrate;

FIG. 9 is a diagram showing a light path on the condition that an electric field is not applied to liquid crystal molecules in the lenticular lens shown in FIG. 6;

FIG. 10 is a diagram showing the light path on the condition that the electric field is applied to the liquid crystal molecules in the lenticular lens shown in FIG. 6;

FIG. 11 is a perspective view showing a structure of the lenticular lens according to a second embodiment of the present invention;

FIG. 12 is a diagram showing a process of exposing an ion-beam in the process of forming an alignment film of the lenticular lens shown in FIG. 11;

FIG. 13 is a diagram showing a light path on the condition that an electric field is not applied to liquid crystal molecules in the lenticular lens shown in FIG. 11; and

FIG. 14 is a diagram showing the light path on the condition that the electric field is applied to the liquid crystal molecules in the lenticular lens shown in FIG. 11.

### DETAILED DESCRIPTION OF THE ILLUSTRATED EMBODIMENTS

References will now be made in detail to embodiments of the present invention, example of which is illustrated in the accompanying drawings.

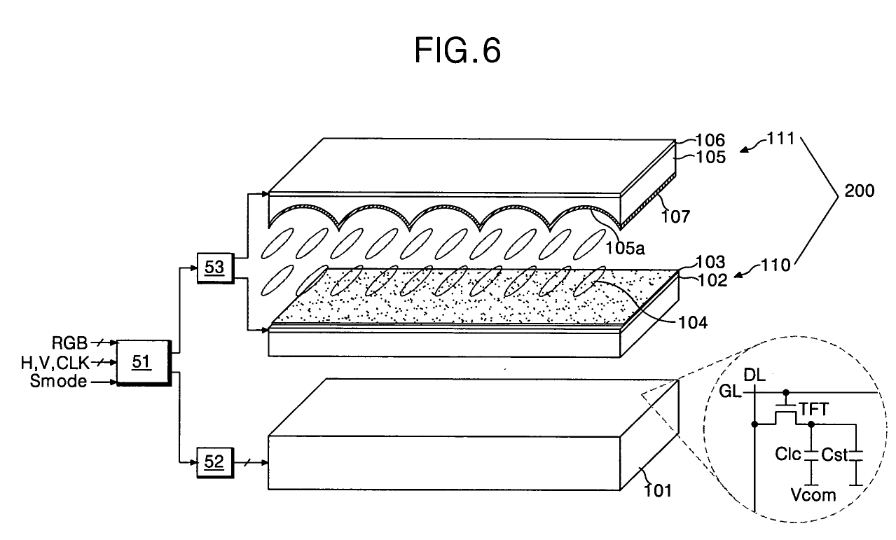

Hereinafter, embodiments of the present invention will be described in detail with reference to FIG. 6 to FIG. 14.

Referring to FIG. 6, a stereoscopic image display device according to a first embodiment of the present invention may include a display panel 101 and a liquid crystal lenticular lens 200 spaced a predetermined distance from the display panel 101.

The display panel 101 may include a flat display panel such as a liquid crystal display (hereinafter, referred to as “LCD”), a field emission display (hereinafter, referred to as “FED”), a plasma display panel (hereinafter, referred to as “PDP”), and an organic light emitting diode (hereinafter, referred to as “OLED”), etc.

A liquid crystal display panel will be primarily described as an example of the display panel 101. A liquid crystal display panel may include active switching devices including data signal lines DL and scanning signal lines GL with switching data supplied to each sub pixel in response to a scanning signal. The switching devices may include a thin film transistor (hereinafter, referred to as “TFT”) supplying a data signal from the data signal lines DL to a pixel electrode of a liquid crystal cell Clc in response to the scanning signal. A common voltage Vcom may be supplied to a common electrode opposed to a pixel electrode of the liquid crystal cell Clc. A mark “Cst” described within a circle represents a storage capacitor that may constantly maintain a voltage of the liquid crystal cell Clc.

Display panel 101 may display a two-dimensional image in accordance with an image source and a two-dimensional mode selection signal. Display panel 101 may display a three-dimensional stereoscopic image in accordance with an image source in which a left eye image data and a right eye image data are separated from each other and a three-dimensional mode selection signal.

A liquid crystal lenticular lens 200 may include an upper plate 111 and a lower plate 110 arranged in opposition to each other with a liquid crystal layer therebetween. The liquid crystal layer may be electrically controlled. Further, the liquid crystal lenticular lens 200 may transmit a light from the display panel 101 in two-dimensional image mode without substantial alteration, and in three-dimensional image mode may refract a light from the display panel 101 to separate a path of a light corresponding to a left eye image and a path of a light corresponding to a right eye image.

An upper plate 111 of the liquid crystal lenticular lens 200 may include a transparent electrode 106, a transparent substrate 105 provided on the transparent electrode 106, and an upper alignment film 107 provided on the transparent substrate 105. A carving pattern 105a may be formed as a plurality of lens surfaces having a curved surface shape on the transparent substrate 105.

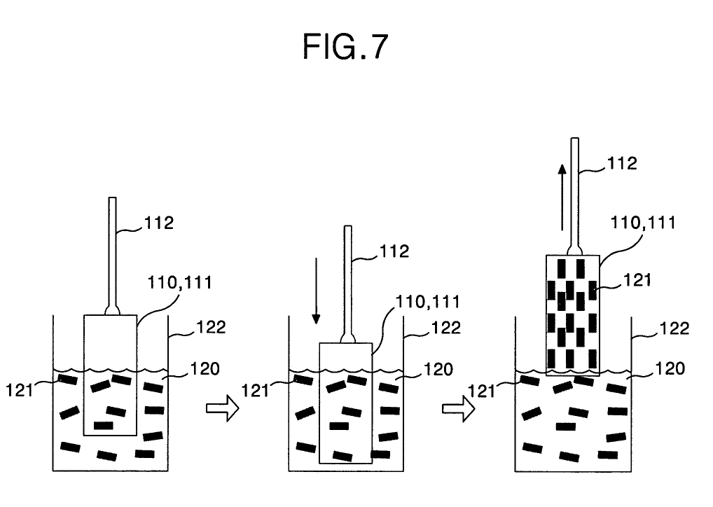

An upper alignment film 107 may be formed at the carving pattern 105a and may be formed on the transparent substrate 105 of the upper plate 111. By a process shown in FIG. 7, a carbon nano-tube (hereinafter, referred to as “CNT”) may be assembled and oriented on a surface of the upper alignment film 107, and a pre-tilt angle of liquid crystal molecules 104 may be determined by the CNTs.

A lower plate 110 of the liquid crystal lenticular lens 200 may include a transparent electrode 102 provided on a lower transparent substrate, and a lower alignment film 103 coated on the transparent electrode 102. The lower alignment film 103 may include a polyimide alignment film and may be formed by a process of rubbing the polyimide alignment film, or may include a CNT film like the upper alignment film 107 to determine a pre-tilt angle of the liquid crystal molecules 104 at the lower plate 110.

Liquid crystal molecules 104 between the upper plate 111 and the lower plate 110 may be a positive liquid crystal. The positive liquid crystal may be aligned in a substantially horizontal direction by the upper alignment film 107 and the lower alignment film 103.

FIG. 7 shows a process of assembling CNT on an upper alignment film 107 and/or a lower alignment film 103 step by step.

Referring to FIG. 7, a method of aligning the liquid crystal according to an embodiment of the present invention will be described as follows. First, an aqueous solution 120 uniformly mixed with CNTs 121 may be put in a water tank 122. Next, a suspension jig 112 attached to the upper plate 111 or the lower plate 110 may be dropped to dip the upper plate 111 or the lower plate 110 into the water tank 122. After a predetermined time goes by, the suspension jig 112 may be raised to lift the dipped transparent substrate. CNTs 121 are attached to the surface of the lifted upper plate 111 or the lifted lower plate 110. Last, moisture left at the upper plate 111 or the lower plate 110 may be removed by a natural dry or a heat treatment to complete the upper alignment film 107 or the lower alignment film 103.

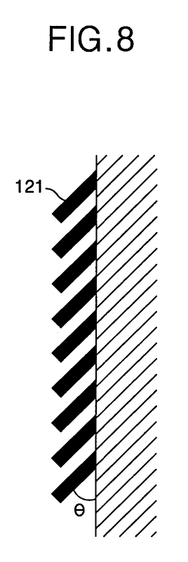

Referring to FIG. 8, an angle θ between the CNT 121 of the alignment films 107 and 103 and the upper plate 111 or the lower plate 110 determine a pre-tilt angle of the liquid crystal molecules 104. Alignment films 107 and 103 may be provided at the upper plate 111 or the lower plate 110. Furthermore, an angle θ between the CNT 121 and a surface of the upper plate 111 or the lower plate 110 may be controlled in accordance with a speed dropping into the aqueous solution 120 and a speed rising from the aqueous solution 120. The angle θ between the CNT and the upper plate 111 or the lower plate 110 is decreased as the speed dropping into the aqueous solution 120 is increased and as the speed rising from the aqueous solution 120 is increased. On the other hand, the angle θ between the CNT and the upper plate 111 or the lower plate 110 is increased as the speed dropping into the aqueous solution 120 is decreased and a speed rising from the aqueous solution 120 is decreased.

Liquid crystal molecules 104 may be uniformly aligned at an interface with the upper plate 111 and at an interface with the lower plate 110 by anchoring energy of the upper alignment film 107 and the lower alignment film 103. Accordingly, a switching speed of the liquid crystal molecules 104 is fast and the liquid crystal molecules become uniform.

The upper transparent electrode 106 and the lower transparent electrode 102 have conductivity, and may be formed of any transparent electrode material having a high transmittance, for example, ITO (Indium tin oxide), IZO (Indium Zinc Oxide), etc to supply a driving voltage supplied from a driving circuit to the liquid crystal molecules 104.

The stereoscopic image display device according to the first embodiment of the present invention may include further a lens driving circuit 53, a display driving circuit 52, and a control circuit 51.

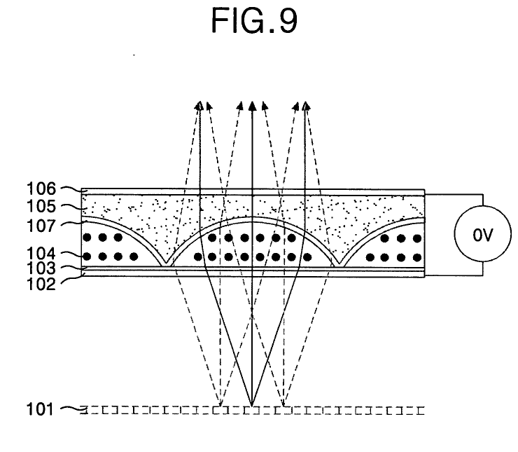

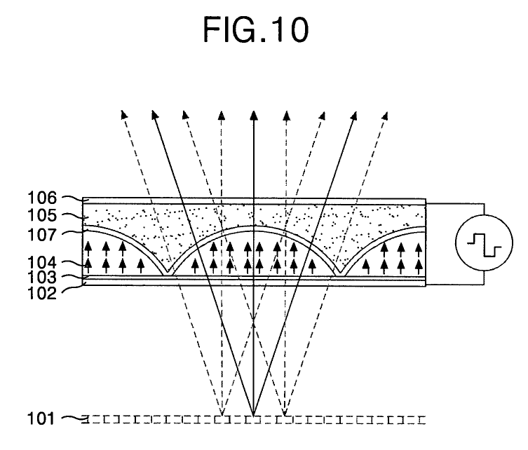

The lens driving circuit 53 may supply a driving voltage to the upper transparent electrode 106 and the lower transparent electrode 102 of a liquid crystal lenticular lens 200 under the control of the control circuit 51. The lens driving circuit 53 may supply a driving voltage having no potential difference to the upper transparent electrode 106 and the lower transparent electrode 102 in the three-dimensional image mode as shown in FIG. 9. The lens driving circuit 53 may supply a driving voltage having a potential difference to the upper transparent electrode 106 and the lower transparent electrode 102 in the two-dimensional image mode as shown in FIG. 10.

The display driving circuit 52 may include a data driving circuit and a scan driving circuit. The data driving circuit may convert a digital video data into an analog data voltage or a data current to supply them to the data signal lines DL, and the scan driving circuit may sequentially supply a scanning signal to the scanning signal lines GL.

The control circuit 51 may be supplied with digital video data from an image source to supply them to a data driving circuit of the display driving circuit 52. Furthermore, the control circuit 51 may be supplied with a timing signal such as a horizontal synchronizing signal H, a vertical synchronizing signal V, and a clock signal CLK, etc to generate timing control signals, thereby controlling the data driving circuit and the scan driving circuit. The timing control signal may control each operation timing of the data driving circuit and the scan driving circuit of the display driving circuit 52.

The control circuit 51 may be supplied with a mode selection signal Smode to control the lens driving circuit 53. The mode selection signal Smode may selectively indicate any one of the two-dimensional image mode and the three-dimensional image mode. The mode selection signal Smode may be supplied from an image source recognizing the two-dimensional image and the three-dimensional image. Further, the mode selection signal Smode may be generated by a user data. In this case, the user data may be inputted from a user interface. The user interface may be supplied with the mode selection signal Smode via a touch panel, an on screen display (hereinafter, referred to as “OSD”), or a user input device such as a mouse and a keyboard, etc to transmit it to the control circuit 51. The touch panel may be arranged at a front of the liquid crystal lenticular lens 200 and touched by the user. The OSD may be realized by software.

An operation of the stereoscopic image display device according to the first embodiment of the present invention will be described with reference to FIG. 9 and FIG. 10.

In the three-dimensional image mode, the transparent electrodes 106 and 102 of the liquid crystal lenticular lens 200 according to the embodiment of the present invention are not applied with the driving voltage or may be supplied with the driving voltage having no potential difference as shown in FIG. 9. The liquid crystal molecules 104 may be aligned in a substantially horizontal direction by the upper alignment film 107 and the lower alignment film 106 in this condition. A refractive index of the liquid crystal layer may be a minor direction refractive index of the liquid crystal molecules 104 more than a refractive index of the transparent substrate 105. Accordingly, the liquid crystal layer may function as a convex lens and separate a light of the right eye image and a light of the left eye image incident from the display panel 101.

In the two-dimensional image mode, the transparent electrodes 106 and 102 of the liquid crystal lenticular lens 200 may be supplied with a predetermined driving voltage having a potential difference as shown in FIG. 10. Since an electric field generated by the driving voltage may be formed in a vertical direction between the upper plate 111 and the lower plate 110, the positive liquid crystal molecules 104 may be rotated, so that a major axis direction thereof is substantially in parallel to an electric field direction. Thus, the positive liquid crystal molecules 104 may be aligned in a substantially vertical direction. The refractive index of such a liquid crystal layer and the refractive index of the transparent substrate 105 may be substantially the same each other. Accordingly, a light irradiated from the display panel 101 may be transmitted into the liquid crystal layer of the liquid crystal lenticular lens and the transparent substrates without substantial alteration.

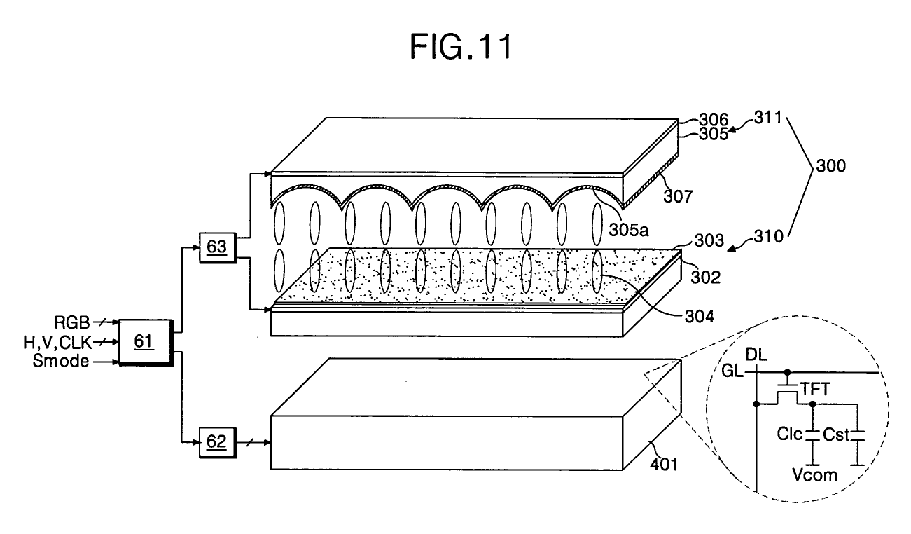

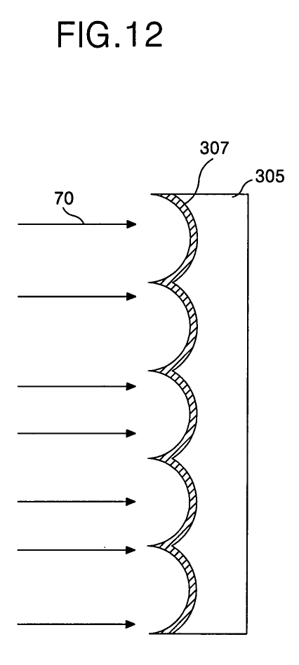

FIG. 11 and FIG. 12 show a stereoscopic image display device according to a second embodiment of the present invention.

Referring to FIG. 11 and FIG. 12, the stereoscopic image display device according to the second embodiment of the present invention may include a display panel 401, and a liquid crystal lenticular lens 300 spaced a predetermined distance from the display panel 401.

The display panel 401 may include of a flat display panel such as a liquid crystal display, a field emission display, a plasma display panel, and an organic light emitting diode, etc.

A liquid crystal display panel will be primarily described as an example of the display panel 401. The liquid crystal display panel may include active switching devices including data signal lines DL and scanning signal lines GL with switching data supplied to each sub pixel in response to a scanning signal. The switching devices include a thin film transistor (hereinafter, referred to as “TFT”) supplying a data signal from the data signal lines DL to a pixel electrode of a liquid crystal cell Clc in response to the scanning signal. A common voltage Vcom may be supplied to a common electrode opposed to a pixel electrode of the liquid crystal cell Clc. A mark “Cst” described within a circle represents a storage capacitor constantly maintaining a voltage of the liquid crystal cell Clc.

Such a display panel 401 may display a two-dimensional image in accordance with an image source and a two-dimensional mode selection signal. Display panel 101 may display a three-dimensional stereoscopic image in accordance with an image source, in which a left eye image data and a right eye image data are separated from each other, and a three dimensional mode selection signal mode selection signal.

A liquid crystal lenticular lens 300 may include an upper plate 311 and a lower plate 310 arranged in opposition to each other with having a liquid crystal layer therebetween. The liquid crystal layer may be electrically controlled. Further, the liquid crystal lenticular lens 300 may transmit a light from the display device 401 in the two-dimensional image mode without substantial alteration, in three dimensional image mode may refract a light from the display device 401 to separate a path of a light corresponding to the left eye image and a path of a light corresponding to the right eye image.

An upper plate 311 of the liquid crystal lenticular lens 300 may include a transparent electrode 306, a transparent substrate 305 provided on the transparent electrode 306, and an upper alignment film 307 provided on the transparent substrate 305. A carving pattern 305a may be formed as a plurality of curved surfaces of concave lens shape on the transparent substrate 305.

The upper alignment film 307 may be formed at the carving pattern 105a and may be formed of amorphous SiOx (hereinafter, referred to as “a-SiOx”) film to uniformly align the liquid crystal molecules 304 in a substantially vertical direction. The a-SiOx film of the upper alignment film 307 may have a constant thickness on the carving pattern 305a of the transparent substrate 305 and may be formed by a sputtering method. Next, the disposed a-SiOx film may be exposed at the ion-beam to generate an anchoring energy which binds the liquid crystal molecules 304 at a surface thereof. A pre-tilt angle of the liquid crystal molecules 304 adjacent to such an upper alignment film 307 may be controlled in accordance with an irradiating direction 70 of the ion-beam. In other words, the liquid crystal molecules 304 may be pre-tilted in the irradiating direction 70 of the ion-beam. Thus, if the irradiating direction 70 of the ion-beam and a tilt angle of the a-SiOx film exposing at the ion-beam are adjusted, a pre-tilt angle of the liquid crystal molecules 305 may be adjusted.

The lower plate 110 of the liquid crystal lenticular lens 300 may include a transparent electrode 302 provided on a lower transparent substrate, and a lower alignment film 303 coated on the transparent electrode 302. The lower alignment film 303 may include a polyimide alignment film or the a-SiOx film, and a pre-tilt of the liquid crystal molecules may be determined 304 by a rubbing process or an ion-beam exposing process. The lower alignment film 303 may be formed on the lower plate 110 by a process which uniformly forms the polyimide alignment film, and a process which rubs a surface of the polyimide alignment film like the related art. Furthermore, the lower alignment film 303 may be formed on the lower plate 110 by a process which forms the upper alignment film 307, such as, a process which disposes the a-SiOx film, and a process which exposes the a-SiOx film at the ion-beam.

The liquid crystal molecules 304 between the upper plate 111 and the lower plate 110 may be a negative liquid crystal. In the negative liquid crystal, a minor axis direction dielectric constant (ε⊥) of the liquid crystal molecules may be more than a major axis direction dielectric constant (ε∥), that is, Δε<0, and may be aligned in a substantially vertical direction by the upper alignment film 307 and the lower alignment film 303. Further, the minor axis direction of the liquid crystal molecules may be aligned substantially in parallel in a direction of an applying electric field.

The liquid crystal molecules 304 may be uniformly aligned at an interface with the upper plate and at an interface with the lower plate by anchoring energy of the upper alignment film 307 and the lower alignment film 303. Accordingly, a switching speed of the liquid crystal molecules 304 is fast and the liquid crystal molecules become uniform.

The upper transparent electrode 306 and the lower transparent electrode 302 have conductivity and may be formed of any transparent material having a high transmittance, for example, ITO (Indium tin oxide), IZO (Indium Zinc Oxide), etc to supply a driving voltage supplied from a driving circuit to the liquid crystal molecules 304.

The stereoscopic image display device according to the second embodiment of the present invention may include a lens driving circuit 63, a display driving circuit 62, and a control circuit 61.

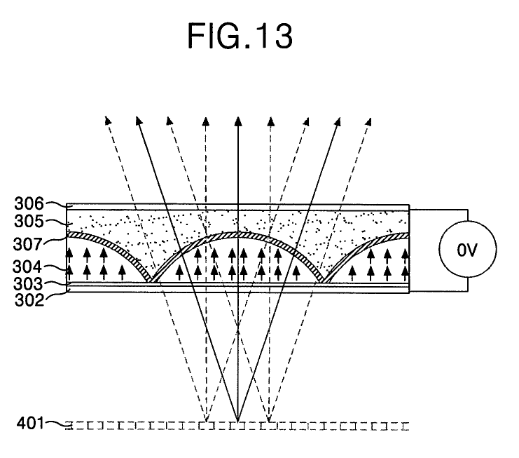

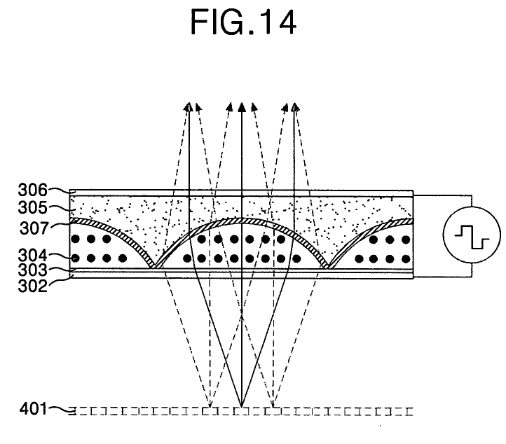

The lens driving circuit 63 may supply a driving voltage to the upper transparent electrode 306 and the lower transparent electrode 302 of a liquid crystal lenticular lens 300 under the control of the control circuit 61. The lens driving circuit 63 may supply a driving voltage having a potential difference to the upper transparent electrode 306 and the lower transparent electrode 302 in the three-dimensional image mode as shown in FIG. 14. The lens driving circuit 63 may supply a driving voltage having no potential difference to the upper transparent electrode 306 and the lower transparent electrode 302 in the two-dimensional image mode as shown in FIG. 13.

The display driving circuit 62 may include a data driving circuit and a scan driving circuit. In this case, the data driving circuit may convert a digital video data into an analog data voltage or a data current to supply them to the data signal lines DL, and the scan driving circuit may sequentially supply a scanning signal to the scanning signal lines GL.

The control circuit 61 may be supplied with digital video data from an image source to supply them to a data driving circuit of the display driving circuit 62. The control circuit 61 may be supplied with a timing signal such as a horizontal synchronizing signal H, a vertical synchronizing signal V, and a clock signal CLK, etc to generate timing control signals, thereby controlling the data driving circuit and the scan driving circuit. The timing control signal may control each operation timing of the data driving circuit and the scan driving circuit of the display driving circuit 62.

The control circuit 61 may be supplied with a mode selection signal Smode to control the lens driving circuit 63. The mode selection signal Smode may selectively indicate any one of the two-dimensional image mode and the three-dimensional image mode. The mode selection signal Smode may be supplied from an image source recognizing the two-dimensional image and the three-dimensional image. Further, the mode selection signal Smode may be generated by a user data. In this case, the user data is inputted from a user interface. The user interface may be supplied with the mode selection signal Smode via a touch panel, an on screen display (hereinafter, referred to as “OSD”), or a user input device such as a mouse and a keyboard, etc to transmit it to the control circuit 61. The touch panel may be arranged at a front of the liquid crystal lenticular lens 200 and may be touched by the user. The on screen display is realized by software.

An operation of the stereoscopic image display device according to the second embodiment of the present invention will be described with reference to FIG. 13 and FIG. 14.

In the two-dimensional image mode, the transparent electrodes 306 and 302 of the liquid crystal lenticular lens 300 according to the embodiment of the present invention are not applied with the driving voltage or may be supplied with the driving voltage having no potential difference as shown in FIG. 13. The liquid crystal molecules 304 may be aligned in a substantially vertical direction between the upper plate 111 and the lower plate 110 by the upper/lower alignment films 307 and 303. A refractive index of the liquid crystal layer and the refractive index of the transparent substrate 305 may be almost the same. Accordingly, light irradiated from the display panel 401 may be transmitted into the liquid crystal layer of the liquid crystal lenticular lens 300 and the transparent substrates without substantial alteration.

In the three-dimensional image mode, the transparent electrodes 302 and 306 of the liquid crystal lenticular lens may be supplied with a predetermined driving voltage having a voltage difference as shown in FIG. 14. Since an electric field generated by the driving voltage may be formed in a substantially vertical direction between the upper plate 111 and the lower plate 110, the negative liquid crystal molecules 304 are rotated, so that a minor axis direction thereof is substantially in parallel to an electric field direction. Thus, the negative liquid crystal molecules 104 may be aligned in a substantially horizontal direction. In this case, a refractive index of the liquid crystal layer may be a minor direction refractive index of the liquid crystal molecules 304 more than a refractive index of the transparent substrate 305. Accordingly, the liquid crystal layer plays a role of a convex lens and separates a light of the right eye image and a light of the left eye image incident from the display device 401.

As described above, the lenticular lens according to the embodiments of the present invention may absorb the CNT on the upper plate having the lens surface, or a a-SiOx film may be formed on the upper plate having the lens surface. The lenticular lens may be exposed to the a-SiOx film at the ion-beam to uniformly provide the alignment film on the lens surface of curved surface type. The method of fabricating the lenticular lens according to the present invention can improve a switching characteristics of the liquid crystal molecules using the alignment film of the upper plate and the alignment film of the lower plate.

Although the present invention has been explained by the embodiments shown in the drawings described above, it should be understood to the ordinary skilled person in the art that the invention is not limited to the embodiments, but rather that various changes or modifications thereof are possible without departing from the spirit of the invention. Accordingly, the scope of the invention shall be determined only by the appended claims and their equivalents.

What is claimed is:

1. A lenticular lens, comprising:
an upper plate including an upper transparent electrode and having a plurality of lens surfaces having a curved surface shape;
an upper alignment film on the lens surfaces;
a lower plate having a lower transparent electrode and a lower alignment film; and
a liquid crystal layer between the upper plate and the lower plate to be driven by an electric field applied by the upper transparent electrode and the lower transparent electrode.

2. The lenticular lens of claim 1, wherein the upper alignment film includes a carbon nano-tube.

3. The lenticular lens of claim 2, wherein the lower alignment film includes at least one of a polyimide and the carbon nano-tube.

4. The lenticular lens as claimed in claim 3, wherein the liquid crystal layer is aligned in a substantially horizontal direction, and includes a positive liquid crystal that a major axis direction is aligned substantially in parallel to a direction of the electric field when the electric field is applied.

5. The lenticular lens as claimed in claim 1, wherein the upper alignment film includes an amorphous SiOx.

6. The lenticular lens as claimed in claim 5, wherein the lower alignment film includes at least one of a polyimide and the amorphous SiOx.

7. The lenticular lens as claimed in claim 6, wherein the liquid crystal layer is aligned in a substantially vertical direction, and includes a negative liquid crystal that a minor axis direction is aligned substantially in parallel to a direction of the electric field when the electric field is applied.

8. A method of fabricating a lenticular lens, comprising:
preparing an upper plate having an upper transparent electrode and a plurality of lens surfaces having a curved surface shape;
forming an upper alignment film at the lens surfaces;
preparing a lower plate having a lower transparent electrode;
forming a lower alignment film at the lower plate; and
forming a liquid crystal layer adjacent to the alignment films between the upper plate and the lower plate.

9. The method of fabricating the lenticular lens as claimed in claim 8, wherein the step of forming an upper alignment film at the lens surface includes:
preparing an aqueous solution uniformly mixed with carbon nano-tubes, and storing the aqueous solution in a water tank;
dipping a substrate of an upper plate having a lens surface of curved surface type into an aqueous solution within the water tank to absorb the carbon nano-tubes on the substrate; and
lifting the substrate with the carbon nano-tubes from the aqueous solution, and then removing moisture left on the substrate.

10. The method of fabricating the lenticular lens as claimed in claim 9, wherein the lower alignment film includes at least one of a polyimide and a carbon nano-tube.

11. The method of fabricating the lenticular lens as claimed in claim 10, wherein the step of forming the lower alignment film includes:
dipping a substrate of the lower plate into an aqueous solution within the water tank to absorb the carbon nano-tubes on the substrate; and
lifting the substrate with the carbon nano-tubes from the aqueous solution, and then removing moisture left on the substrate.

12. The method of fabricating the lenticular lens as claimed in claim 10, wherein the step of forming the lower alignment film includes:
forming a polyimide film on a substrate of the lower plate; and
rubbing the polyimide film.

13. The method of fabricating the lenticular lens as claimed in claim 9, wherein the liquid crystal layer is aligned in a substantially horizontal direction, and includes a positive liquid crystal that a major axis direction is aligned substantially in parallel to a direction of the electric field when the electric field is applied.

14. The method of fabricating the lenticular lens as claimed in claim 8, wherein the step of forming an upper alignment film at the lens surfaces includes:
forming an amorphous SiOx film on the lens surface; and
exposing the amorphous SiOx film to an ion-beam.

15. The method of fabricating the lenticular lens as claimed in claim 14, wherein the lower alignment film includes at least one of a polyimide and the amorphous SiOx.

16. The method of fabricating the lenticular lens as claimed in claim 15, wherein the step of forming the lower alignment film includes:
forming an amorphous SiOx film on the lower plate; and
exposing the amorphous SiOx film provided on the lower plate to an ion-beam.

17. The method of fabricating the lenticular lens as claimed in claim 15, wherein the step of forming the lower alignment film includes:
forming a polyimide film on a substrate of the lower plate; and
rubbing the polyimide film.

18. The method of fabricating the lenticular lens as claimed in claim 14, wherein the liquid crystal layer is aligned in a substantially vertical direction, and includes a negative liquid crystal that a minor axis direction is aligned substantially in parallel to a direction of the electric field when the electric field is applied.

19. A stereoscopic image display device, comprising:
a display panel; and
a liquid crystal lenticular lens spaced a predetermined distance from the display panel, the lenticular lens including:
an upper plate having an upper transparent electrode and a plurality of lens surfaces having a curved surface shape;
an upper alignment film uniformly on the lens surfaces;
a lower plate having a lower transparent electrode and a lower alignment film; and
a liquid crystal layer provided between the upper plate and the lower plate to be driven by an electric field applied by the upper transparent electrode and the lower transparent electrode.

20. The display device as claimed in claim 19, wherein the upper alignment film includes a carbon nano-tube.

21. The display device as claimed in claim 20, wherein the lower alignment film includes any one of a polyimide and the carbon nano-tube.

22. The display device as claimed in claim 21, wherein the liquid crystal layer is aligned in a substantially horizontal direction, and includes a positive liquid crystal that a major axis direction is aligned substantially in parallel to a direction of the electric field when the electric field is applied.

23. The display device as claimed in claim 19, wherein the upper alignment film includes an amorphous SiOx.

24. The display device as claimed in claim 23, wherein the lower alignment film includes any one of a polyimide and the amorphous SiOx.

25. The display device as claimed in claim 24, wherein the liquid crystal layer is aligned in a substantially vertical direction, and includes a negative liquid crystal that a minor axis direction is aligned substantially in parallel to a direction of the electric field when the electric field is applied.
